(19) United States
(12) Patent Application Publication
(10) Pub. No.: US 2022/0301925 A1
(43) Pub. Date: Sep. 22, 2022

(54) METHOD OF MANUFACTURING SEMICONDUCTOR DEVICE AND ETCHING METHOD

(71) Applicant: Kioxia Corporation, Tokyo (JP)

(72) Inventor: Takaya ISHINO, Yokkaichi Mie (JP)

(73) Assignee: Kioxia Corporation, Tokyo (JP)

(21) Appl. No.: 17/475,646

(22) Filed: Sep. 15, 2021

(30) Foreign Application Priority Data
Mar. 18, 2021 (JP) 2021-045133

(51) Int. Cl. H01L 21/768; H01L 21/02

(52) U.S. Cl. CPC H01L 21/76816; H01L 21/76826; H01L 21/0217; H01L 21/76831

(57) ABSTRACT

A method of manufacturing a semiconductor device according to an embodiment includes: forming a multilayer structure in which first insulating layers and second insulating layers are alternately stacked; and forming a plurality of contact holes in the multilayer structure, each of the contract holes having a different aspect ratio, the forming of one of the plurality of contact holes including a first step of etching at least one of the first insulating layers and a second step of etching at least one of the second insulating layers, and the second step is performed by using a mixed gas including a CHF gas which contains carbon, hydrogen, and fluorine and hydrogen gas.

### CROSS REFERENCE TO RELATED APPLICATIONS

This application is based upon and claims the benefit of priority from the prior Japanese Patent Application No. 2021-045133, filed on Mar. 18, 2021, the entire contents of which are incorporated herein by reference.

### FIELD

An embodiment described herein relates generally to a method of manufacturing a semiconductor device and an etching method.

### BACKGROUND

A semiconductor device having a multilayer structure, in which conductive layers and insulating layers are alternately stacked, is known. When the multilayer structure is formed, first insulating layers and second insulating layers acting as sacrifice layers are alternately stacked, contact holes each reaching any of the second insulating layers are formed, the contact holes are filled with a metal, for example, and then the second insulating layers are replaced with conductive layers.

When the contact holes are formed, a first contact hole with a high aspect ratio and a second contact hole with a low aspect ratio are processed at the same time. In such a case, while the second contact hole is processed, the second insulating layer that acts as an etching stopper may also be penetrated.

### BRIEF DESCRIPTION OF THE DRAWINGS

FIG. 1 is a perspective view illustrating a semiconductor device according to an embodiment.

FIG. 2 is a cross-sectional view showing a multilayer wiring structure.

FIG. 3A is a plan view and FIG. 3B is a cross-sectional view showing a step of a method of manufacturing the semiconductor device according to the embodiment.

FIG. 4A is a plan view and FIG. 4B is a cross-sectional view showing a step of the method of manufacturing the semiconductor device according to the embodiment.

FIG. 5A is a plan view and FIG. 5B is a cross-sectional view showing a step of the method of manufacturing the semiconductor device according to the embodiment.

FIG. 6A is a plan view and FIG. 6B is a cross-sectional view showing a step of the method of manufacturing the semiconductor device according to the embodiment.

FIG. 7 is a cross-sectional view showing a step of the method of manufacturing the semiconductor device according to the embodiment.

FIG. 8 is a cross-sectional view showing a step of the method of manufacturing the semiconductor device according to the embodiment.

FIG. 9 is a cross-sectional view showing a step of the method of manufacturing the semiconductor device according to the embodiment.

FIG. 10 is a cross-sectional view showing a step of the method of manufacturing the semiconductor device according to the embodiment.

FIG. 11 is a graph showing the dependence of etching rate on aspect ratio.

FIG. 12 is a graph showing etching rates of CxHyFz gases and gases obtained by adding hydrogen to the CxHyFz gases.

### DETAILED DESCRIPTION

An embodiment will be described below with reference to the accompanying drawings. The drawings are made in a schematic or conceptional manner, and the relationship between the thickness and the width of each element and the ratio between elements, for example, do not always match those of the actual cases. The dimensions of each element and the ratio between elements may differ in several drawings illustrating the same portion. In the specification and the drawings, the same reference numeral is assigned to the same element, and the detailed description of such an element is repeated only when it is necessarily to do so.

### Embodiment

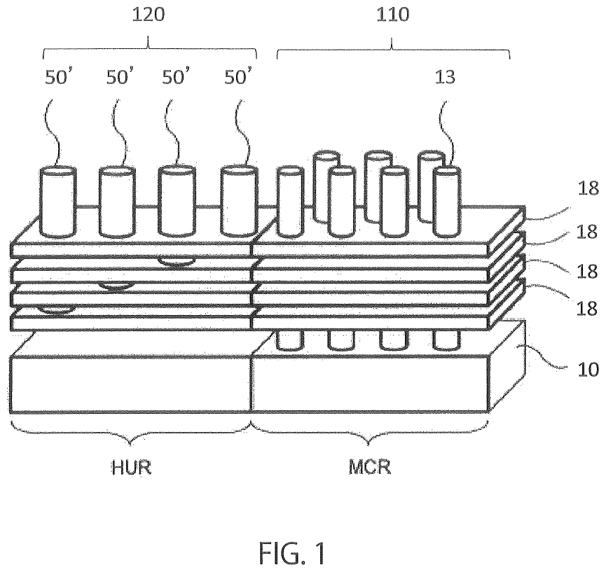

FIG. 1 is a perspective view showing a memory cell region MCR and a pull-out region HUR of a semiconductor device according to an embodiment. In order to avoid complication, only conductive elements are shown and hatching is omitted in FIG. 1. The portions where the elements are not shown in FIG. 1 are insulated with an insulating material such as silicon oxide.

In the memory cell region MCR, a memory cell array 110 is disposed on a semiconductor substrate 10 of monocrystalline silicon. The memory cell array 110 includes a plurality of insulating layers and a plurality of conductive layers 18 extending in parallel to the surface of the semiconductor substrate 10. The memory cell array 110 has a multilayer structure in which the insulating layers and the conductive layers are alternately stacked. Although only four conductive layers 18 are shown in FIG. 1, the number of conductive layers is much more than four, such as 33 or 65. The conductive layers 18 correspond to source side select gate lines, word lines, or drain side select gate lines connected to transistors.

Memory pillars 13 are formed to penetrate the insulating layers and the conductive layers 18 in the memory cell region MCR. Each of the memory pillars 13 has a cylindrical shape, and includes a silicon oxide film, a silicon nitride film, a silicon oxynitride film, an amorphous or polycrystalline silicon film, and a silicon oxide film disposed in this order from the outer side to the inner side. Portions surrounded by the conductive layers 18 serve as portions of nonvolatile memory cells, which trap carriers to the silicon nitride film.

A multilayer wiring structure 120 is disposed on a semiconductor substrate 10 of monocrystalline silicon in the pull-out region HUR. The pull-out region HUR also includes the insulating layers and the conductive layers 18 that extend from the memory cell region MCR. The insulating layers and the conductive layers 18 of the multilayer wiring structure 120 includes are in parallel with the surface of the semiconductor substrate 10. The multilayer wiring structure 120 has a multilayer structure in which the insulating layers and the conductive layers 18 are alternately stacked. Although only four conductive layers 18 are shown in FIG. 1, the number of conductive layers is much more than four, such as 33 or 65.

The conductive layers 18 in the pull-out region HUR correspond to wirings pulled out from the word lines, the source side select gate lines, or the drain side select gate lines of the memory cell region MCR.

The conductive layers 18 in the pull-out region HUR are connected to corresponding contact plugs 50′. Each of the contact plugs 50′ are pulled out above the multilayer wiring structure 120 through a contact hole penetrating the insulating layers and the conductive layers 18.

The contact plugs 50′ are greater in diameter and cross-sectional area than the memory pillars 13. Furthermore, the contact plugs 50′ are greater in arrangement density than the memory pillars 13. In other words, the contact plugs 50′ do not need to be disposed with a high density, like the memory pillars 13.

### (Multilayer Wiring Structure)

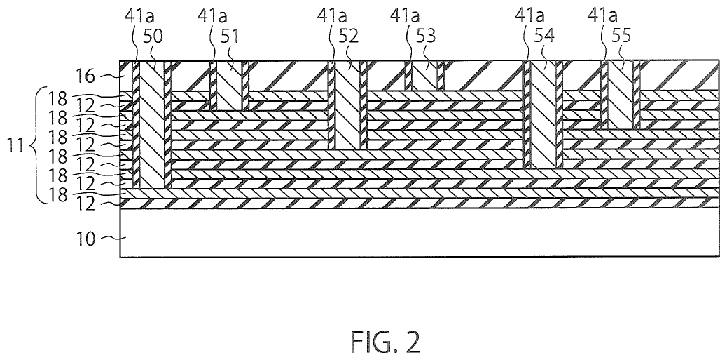

FIG. 2 is a cross-sectional view illustrating the multilayer wiring structure 120. In FIG. 2, the contact plugs 50′ shown in FIG. 1 are shown as contact plugs 50, 51, 52, 53, 54, and 55. The multilayer wiring structure 120 includes the conductive layers 18 disposed on the semiconductor substrate 10. The conductive layers 18 and the insulating layers 12 are alternately and cyclically stacked in a direction (staking direction) perpendicular to a main surface of the semiconductor substrate 10. Each of the conductive layers 18 is a single layer. Therefore, a cross section of a single conductive layer 18 has a single material continuously extending in the film thickness direction of the conductive layer 18. No interface may be present in the single conductive layer 18. The material of the conductive layer 18 may be, for example, tungsten.

An insulating layer 12 is disposed between two conductive layers 18 that are adjacent to each other in the stacking direction. An insulating layer 12 is also disposed between the semiconductor substrate 10 and the lowermost conductive layer 18. The insulation of the conductive layers 18 adjacent to each other in the stacking direction may be performed by other methods. The material of the insulating layer 12 may be, for example, silicon dioxide (SiO₂), or silicon oxide produced from tetra ethyl ortho silicate (TEOS). The insulating layers 12 are deposited by means of a chemical vapor deposition (CVD) apparatus, for example.

One of the contact plugs 50 to 55 is connected to one of the conductive layers 18 at the bottom of the corresponding contact hole. The length from the top surface of the multilayer wiring structure 120 differs among the contact plugs 50 to 55. The contact plugs 50 to 55 have a cylindrical shape. The material of the contact plugs 50 to 55 may be a metal such as tungsten.

The contact plugs 50 to 55 are insulated from the conductive layers 18 through which they are formed. An insulating film 41a having a cylindrical shape is formed on the inner surface of each of the contact plugs 50 to 55. In other words, the inner surface of each of the contact plugs 50 to 55 is covered with the insulating film 41a. The material of the insulating film 41a is, for example, silicon dioxide (SiO₂), or silicon oxide produced from tetra ethyl ortho silicate (TEOS).

### (Method of Forming Multilayer Wiring Structure)

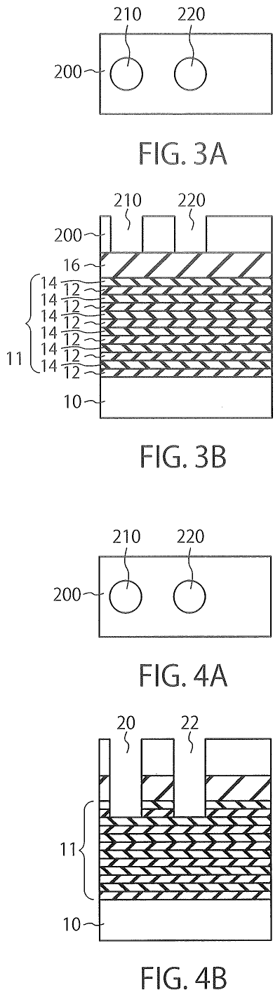

A method of forming the multilayer wiring structure 120 included in the semiconductor device according to the embodiment will be described with reference to FIGS. 3A to 6B. As shown in FIG. 3B, first insulating layers 12 and second insulating layers 14 that serve as sacrifice layers are alternately formed on the silicon substrate (or the silicon layer) 10 to form a multilayer structure 11. The first insulating layers 12 contain silicon oxide, for example, and the second insulating layers 14 contain silicon nitride, for example. An insulating layer 16 containing silicon oxide, for example, is formed on the multilayer structure 11, and a mask 200 is formed on the insulating layer 16. Holes 210 and 220 are then formed through the mask 200 using a photolithographic technique (FIGS. 3A and 3B). FIG. 3A is a plan view and a FIG. 3B is a cross-sectional view.

Thereafter, as shown in FIGS. 4A and 4B, reactive ion etching (RIE) is performed on the insulating layer 16 and the multilayer structure 11 using the mask 200, so as to form contact holes 20 and 22 that reach the second one of the second insulating layers counted from the top of the multilayer structure 11 (FIGS. 4A and 4B). FIG. 4A is a plan view and FIG. 4B is a cross-sectional view. In this etching process, a step of etching the second insulating layers 14 containing silicon nitride, which serve as sacrifice layers, and a step of etching first insulating layers 12 containing silicon oxide, are sequentially performed with different etching gases. The etching gas used for etching the second insulating layers 14 is, for example, a mixed gas obtained by mixing a gas in which the flow ratio of C₃HF₅ and H₂ is 100 to 100 (C₃HF₅/H₂=100/100), O₂ gas, and Ar gas. In other words, an etching gas containing C, H, and F mixed with hydrogen gas at the ratio of 1 to 1 is used. The etching gas used for etching the first insulating layers 12 is, for example, a mixed gas obtained by mixing C₄F₈ gas, CO gas, and Ar gas.

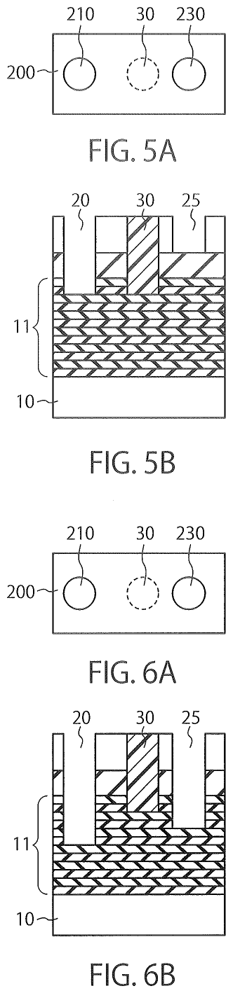

Subsequently, as shown in FIGS. 5A and 5B, the contact hole 22 formed in the multilayer structure 11 and the hole 220 formed in the mask 200 are filled with a photoresist 30, and a new hole 230 is formed through the mask 200. FIG. 5A is a plan view, and FIG. 5B is a cross-sectional view.

Thereafter, dry etching, for example RIE, is performed on the multilayer structure 11 using the mask 200 having the holes 210 and 230, as shown in FIGS. 6A and 6B. In the dry etching process, the step of etching the second insulating layers 14 and the step of etching the first insulating layers 12 described above are repeated until each of the contact holes 20 and 25 has a desired depth. The etching gas used for etching the second insulating layers 14 is a mixed gas obtained by mixing a gas in which C₃HF₅/H₂=100/100, O₂ gas, and Ar gas. In other words, an etching gas containing C, H, and F mixed with hydrogen gas at the ratio of 1 to 1 is used. FIG. 6A is a plan view, and FIG. 6B is a cross-sectional view.

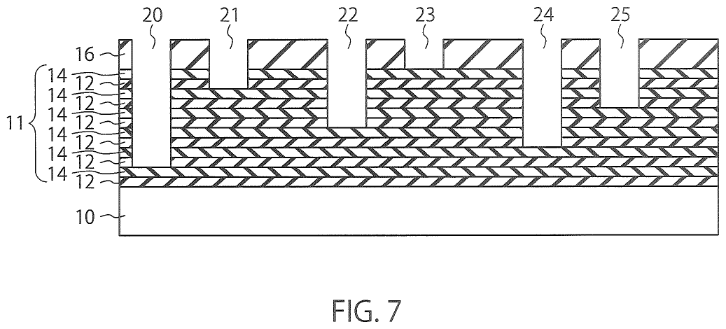

After the above-described steps are repeated, the resist filled into the contact holes are removed. As a result, a plurality of contact holes 20, 21, 22, 23, 24, and 25 that reach any of the second insulating layers are formed through the multilayer structure 11, as shown in FIG. 7.

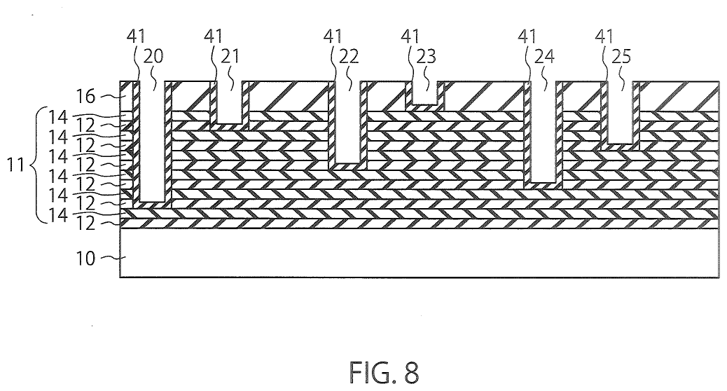

Subsequently, an insulating film 41 of silicon oxide, for example, is formed on the bottom and the side surface of each of the contact holes 20 to 25, as shown in FIG. 8.

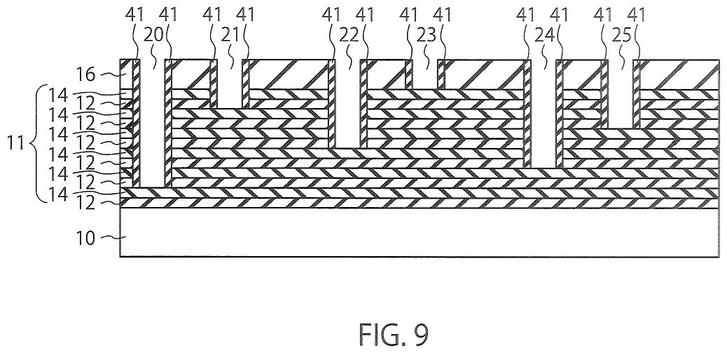

The insulating film 41 formed on the bottom of each of the contact holes 20 to 25 is then removed by RIE, for example, as shown in FIG. 9. The insulating film 41 formed on the side surface of each of the contact holes 20 to 25 is left.

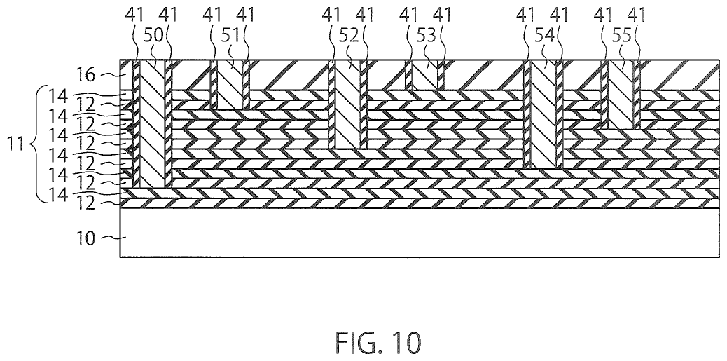

Thereafter, a metal, for example tungsten (W), is filled into the contact holes 20 to 25 by chemical vapor deposition (CVD), for example, as shown in FIG. 10. As a result, the contact plugs 50, 51, 52, 53, 54, and 55 including a metal are formed.

Finally, the second insulating layers 14 are removed by wet etching, and conductive layers 18 of tungsten, for example, are formed by CVD, for example, at the locations where the second insulating layers 14 are removed (FIG. 2). As a result, the semiconductor device is completed. The semiconductor device has the multilayer wiring structure including the alternatively stacked insulating layers and conductive layers, and the contact plugs each connecting to any of the wiring layers.

The etching gas used in the embodiment is a mixed gas in which C₃HF₅ gas is mixed with H₂ gas at the ratio of 1 to 1. The mixing ratio of the C₃HF₅ gas and H₂ gas may be in the range of 1:1 to 1:2 in order to obtain substantially the same effect.

The advantage of the embodiment will now be described below.

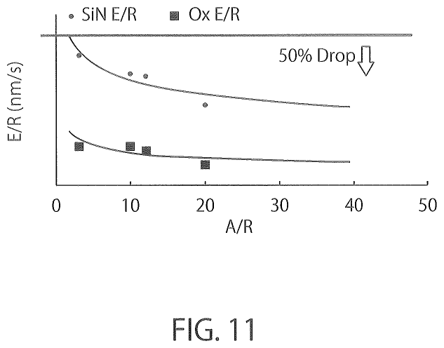

FIG. 11 is a diagram for explaining a method of forming a multilayer wiring structure of a comparative example. FIG. 11 shows a result of measuring the dependence of etching rate on aspect ratio when a mixed gas obtained by mixing CH₂F₂ gas, O₂ gas, and Ar gas with the flow ratio of 70 sccm:21 sccm:164 sccm is used as an etching gas for etching silicon nitride layers in the method of manufacturing the comparative example. In short, the etching gas of the comparative example does not include hydrogen gas. As shown in FIG. 11, the etching rate of a silicon nitride layer with a maximum aspect ratio, for example about 40, is dropped by about 50% as compared with the etching rate of a silicon nitride layer with a minimum aspect ratio.

According to the method of manufacturing the comparative example, the etching rate is reduced for a contact hole with a high aspect ratio. As a result, a contact hole with a low aspect ratio may be overetched. This may cause an insulating layer, which acts as an etching stopper during the etching process of a contact hole having a low aspect ratio, to be penetrated.

The inventors of the present invention considered that in order to solve this problem, the etching rate of the second insulating layers that act as etching stoppers should be set greater than the etching rate of the first insulating layers when contact holes having different aspect ratios are etched with the same type of etching gas in a multilayer structure including alternately stacked first insulating layers and second insulating layers.

A plurality of first insulating layers formed of silicon oxide and a plurality of second insulating layers formed of silicon nitride are prepared. An experiment is performed on those insulating layers in order to find a greatest ratio between the etching rate of the second insulating layers and the etching rate of the first insulating layers, and in turn find an etching gas having a greatest etching selectivity with respect to the second insulating layers. For the experiment, a plurality of etching gases are prepared. Examples of the prepared gases are chain hydrocarbon compounds used for the manufacture of three-dimensional memories, expressed as CₓHyF_{z} (C represents carbon, H represents hydrogen, and F represents fluorine, x is an integer of 3 or more, and y and z are integers of 1 or more), and chain hydrocarbon compounds mixed with hydrogen. Specifically, nine gases are used, including C₄F₈/H₂=80/0, C₄F₈/H₂=80/100, C₄F₈/H₂=80/200, C₃HF₅/H₂=100/0, C₃HF₅/H₂=100/100, C₃HF₅/H₂=100/200, C₃F₈/H₂=100/0, C₃F₈/H₂=100/100, and C₃F₈/H₂=100/200. The symbol “/” means flow ratio. For example, C₃HF₅/H₂=100/0 means an etching gas in which the flow rate of C₃HF₅ is 100 and the flow rate of H₂ is 0.

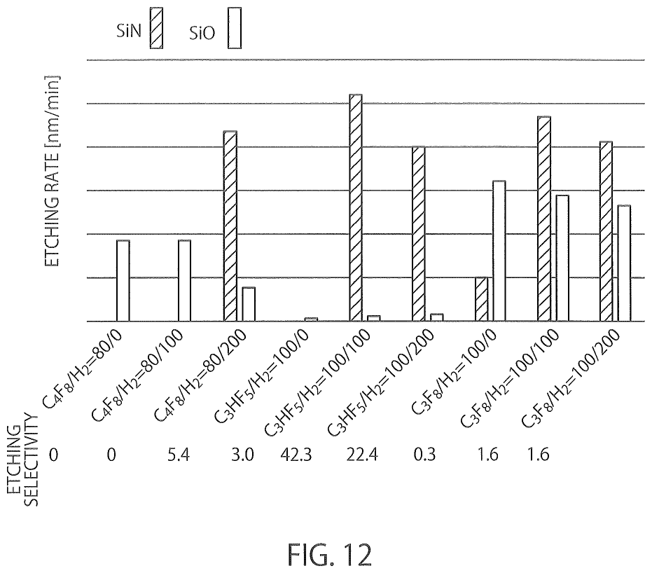

FIG. 12 shows the result of the experiment. In FIG. 12, the horizontal axis shows the aforementioned etching gases, and the vertical axis shows the etching rates when the etching gases are used. The number below each etching gas name shows the etching selectivity of the etching gas with respect to the second insulating layers relative to the first insulating layers, i.e., a value obtained by dividing the etching rate of the second insulating layers by the etching rate of the first insulating layers. In FIG. 12, white columns indicate etching rates of the first insulating layers of silicon oxide, and hatched columns indicate etching rates of the second insulating layers of silicon nitride.

As can be understood from FIG. 12, the etching selectivity of silicon nitride when a fluorinated hydrocarbon compound gas expressed as CₓH_{y}F_{z} (x, y, and z are coefficients) is used alone as the etching gas is lower than the etching selectivity when a mixed gas obtained by adding hydrogen to the fluorinated hydrocarbon compound gas is used. Furthermore, the etching selectivity of silicon nitride when a hydrocarbon compound gas expressed as CₓF_{y} (x and y are coefficients) is used alone as the etching gas is lower than the etching selectivity when a mixed gas obtained by adding hydrogen to the hydrocarbon compound gas is used. Therefore, a mixed gas obtained by adding hydrogen to a gas expressed as CₓH_{y}F_{z} or CₓF_{y} is preferably used. The etching gas with the etching selectivity of 10.0 or more is C₃HF₅/H₂=100/100 or C₃HF₅/H₂=100/200. A gas obtained by adding hydrogen to C₃HF₅ is preferable since the etching selectivity thereof is 20 or more. C₃HF₅/H₂=100/100 is more preferable since the etching selectivity thereof is more than 40. It is therefore preferable that the ratio of hydrogen to the etching gas containing C, H, and F is from 1:1 to 1:2.

It can be understood from the experiment result shown in FIG. 12 that the use of a gas obtained by mixing hydrogen (H₂) gas to a CHF gas containing C, H, and F with the carbon number being 3 or more makes it possible to increase the etching selectivity of an insulating layer of silicon nitride relative to an insulating layer of silicon oxide. If such an etching gas is used for the formation of contact holes each having a different aspect ratio, it is possible to prevent the occurrence of overetching of the insulating layer of silicon nitride that acts as an etching stopper. The gas containing C, H, and F is not limited to C₃HF₅ gas, but may be an etching gas containing one or more of C₃HF₇, C₃H₂F₆, C₃H₃F₅, C₄H₄F₆, C₄H₃F₇, C₄H₂F₈, C₄HF₉, C₅H₆F₆, C₅H₅F₇, C₅H₄F₈, C₅H₃F₉, C₅H₂F₁₀, and C₅HF₁₁ to obtain the same effect.

As described above, according to this embodiment, it is possible to prevent the insulating layer serving as an etching stopper from being entirely etched when contact holes each having a different aspect ratio are formed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a multilayer structure in which first insulating layers and second insulating layers are alternately stacked; and
forming a plurality of contact holes in the multilayer structure, each of the contract holes having a different aspect ratio,
the forming of one of the plurality of contact holes including a first step of etching at least one of the first insulating layers and a second step of etching at least one of the second insulating layers, and
the second step is performed by using a mixed gas including a CHF gas which contains carbon, hydrogen, and fluorine and hydrogen gas.

2. The method according to claim 1, wherein the carbon number of the CHF gas is 3 or more.

3. The method according to claim 1, wherein the CHF gas includes C₃HF₅.

4. The method according to claim 1, wherein a mixture ratio of the CHF gas and the hydrogen gas is in a range from 1:1 to 1:2.

5. The method according to claim 1, wherein the second insulating layers include silicon and nitrogen.

6. The method according to claim 1, wherein the CHF gas is at least one of C₃HF₇, C₃H₂F₆, C₃H₃F₅, C₄H₄F₆, C₄H₃F₇, C₄H₂F₈, C₄HF₉, C₅H₆F₆, C₅H₅F₇, C₅H₄F₈, C₅H₃F₉, C₅H₂F₁₀, or C₅HF₁₁.

7. The method according to claim 1, further comprising:
forming an insulating film on a bottom and a side surface of each of the contact holes;
removing the insulating film on the bottom of each of the contact holes, with the insulating film on the side surface being left;
filling the contact holes with a metal material.

8. The method according to claim 7, further comprising:
removing the second insulating, after filling the contact holes; and
forming wiring layers at locations where the second insulating layer are removed.

9. The method according to claim 1, further comprising:
forming memory pillars in the multilayer structure, the memory pillars being formed in a different region of the contact holes.

10. An etching method comprising:
preparing a film to be processed containing silicon and nitrogen;
etching the film to be processed with a mixed gas containing hydrogen gas and a CHF gas including carbon, hydrogen, and fluorine with the carbon number being 3 or more.

11. The etching method according to claim 10, wherein the CHF gas contains C₃HF₅.

12. The etching method according to claim 10, wherein a mixture ratio of the CHF gas and the hydrogen gas is from 1:1 to 1:2.

13. The method according to claim 10, wherein the CHF gas is at least one of C₃HF₇, C₃H₂F₆, C₃H₃F₅, C₄H₄F₆, C₄H₃F₇, C₄H₂F₈, C₄HF₉, C₅H₆F₆, C₅H₅F₇, C₅H₄F₈, C₅H₃F₉, C₅H₂F₁₀, or C₅HF₁₁.
